(19) United States
(12) Patent Application Publication
(10) Pub. No.: US 2024/0080006 A1
(43) Pub. Date: Mar. 7, 2024

(54) DIFFERENTIAL AMPLIFIER CIRCUIT

(71) Applicant: Nippon Telegraph and Telephone Corporation, Tokyo (JP)

(72) Inventors: Hiroshi Hamada, Tokyo (JP); Hideyuki Nosaka, Tokyo (JP)

(21) Appl. No.: 18/261,940

(22) PCT Filed: Feb. 12, 2021
(86) PCT No.: PCT/JP2021/005282

§ 371 Date: Jul. 18, 2023

(51) Int. Cl. H03F 3/45; H03F 1/30; H03F 1/56

(52) U.S. Cl. CPC H03F 3/45183; H03F 1/301; H03F 1/565; H03F 2200/451

(57) ABSTRACT

An embodiment differential amplifier circuit includes an amplifier section including differential pair transistors to which a differential signal is input and a tail current circuit made up of a short stub provided between a ground terminal of the amplifier section and a ground. In an embodiment, an electrical length of the short stub is shorter than a quarter wavelength of an operation frequency of the differential amplifier circuit.

### CROSS-REFERENCE TO RELATED APPLICATIONS

This application is a national phase entry of PCT Application No. PCT/JP2021/005282, filed on Feb. 12, 2021, which application is hereby incorporated herein by reference.

### TECHNICAL FIELD

The present invention relates to a circuit that handles high-frequency electrical signals, and more particularly, to a differential amplifier circuit.

### BACKGROUND

Among amplifier circuits, a differential amplifier circuit is known to have various useful properties, including a property of amplifying only a differential signal and removing a common mode signal. For example, common mode components are removed by the differential amplifier circuit, and only complete differential signals are generated. By using this differential signal as an LO signal of a differential mixer, LO leakage which often becomes a problem in the mixer can be eliminated (NPL 1). FIG. 14 shows a configuration of a general differential amplifier circuit.

The operation of the differential amplifier circuit of FIG. 14 will be briefly described. A differential signal V_{IN} is input to differential input ports INP and INN of a differential pair consisting of two transistors Q1 and Q2 constituting a source ground amplifier, and an amplified signal V_{OUT} is output from differential output ports OUTP and OUTN. A current source transistor Q3 (tail current source) that applies an appropriate bias current to the transistors Q1 and Q2 is connected to an X point on which source terminals of the differential pair transistors Q1 and Q2 intersect.

Since the transistor Q3 operates as a current source, the bias V_{GG1} is set to such a bias voltage that the transistor Q3 operates in a saturation region. Since the output impedance of the transistor Q3 of the saturation region takes a very high value, the impedance when the ground potential is viewed from the point X reaches a very high value. With this high impedance, the common mode signal input to the transistors Q1 and Q2 is equivalent to the source terminals of the transistors Q1 and Q2 being open. Therefore, the gain (common mode gain) of the differential amplifier circuit to the common mode signal becomes very small.

On the other hand, when a differential signal is input, since the transistors Q1 and Q2 are driven by signals whose phases are inverted, the potential at the point X is fixed to zero, regardless of the impedance of the transistor Q3, by the symmetrical configuration of FIG. 14. Therefore, it becomes equivalent to that the source terminals of the transistors Q1 and Q2 are grounded. The fixing of the point X to the zero potential is called a virtual ground of the differential amplifier circuit. Therefore, the gain (differential gain) of the differential amplifier circuit to the differential signal becomes very large.

An important point here is that the differential amplifier circuit of FIG. 14 has gain selectivity to the mode (common mode or differential) of the input signal. That is, even if a signal in which the common mode signal and the differential signal are mixed is input to the differential input ports INP and INN, only the differential signal is selectively amplified by the differential amplifier circuit, and the differential signal V_{OUT} is output from the differential output ports OUTP and OUTN. The selectivity of the gain is an important characteristic of the differential amplifier circuit. As a performance index of the differential amplifier circuit, a common mode rejection ratio (CMRR) indicating a ratio of a common mode gain to a differential gain is used as a characteristic index.

The problem of the configuration shown in FIG. 14 is power consumption. In the configuration of FIG. 14, there is a problem of an increase in a power supply voltage V_{DD} due to a bias voltage V_{GG1} for operating the transistor Q3 as a current source, that is, an increase in power consumption. That is, since it is required to set the power supply voltage V_{DD} to a voltage corresponding to biasing the two transistors to the saturation region, the power consumption becomes approximately twice as large as that of the normal single-end amplifier circuit. Especially at a frequency of 300 GHz or more, since the gain per transistor stage is small, it is necessary to make the transistors multi-stage, and the power consumption of the differential amplifier circuit inevitably increases. For example, since the power consumption of the differential amplifier circuit disclosed in NPL 2 is 2 W even in a single-end design, when this circuit is differentially used as it is, very large power consumption of 4 W or more occurs.

As a method for solving the problem of power consumption, a configuration in which an inductor L1 is set as a tail current circuit is known as shown in FIG. 15. As a result, since the voltage consumed by the tail current circuit becomes 0, and the power supply voltage V_{DD} becomes the voltage corresponding to one transistor, the power consumption is smaller than that of the configuration of FIG. 14.

In the case of the configuration of FIG. 15, by setting the inductance of the inductor L₁ sufficiently large at the operation frequency of the differential amplifier circuit, the impedance when the ground potential is viewed from the point X becomes large, and the inductor L1 can equivalently have the same effect of the current source as that of FIG. 14.

However, in a frequency band exceeding 300 GHz, even if the inductor L₁ is realized by a winding or the like, since the self-resonance frequency of the inductance L₁ is generally lower than 300 GHz, it becomes difficult to realize the inductor L₁ itself by an integrated circuit process.

According to NPL 3, it is found that an upper limit frequency of the inductor which can be realized by the integrated circuit process is considerably lower than 300 GHz. Even if the inductor can be realized by the integrated circuit process, the layout of the winding inductor becomes asymmetrical. It is difficult to adopt the winding inductor whose layout is asymmetric in the differential amplifier circuit in which symmetry of layout is important.

As described above, in the topology of the conventional differential amplifier circuit, there was no tail current source circuit capable of ensuring a large CMRR while maintaining low power consumption in a frequency band of 300 GHz or more.

### CITATION LIST

### Non Patent Literature

NPL 1—Jeng-Han Tsai, et al., “A25-75 GHz Broadband Gilbert-Cell Mixer Using 90-nm CMOS Technology,” IEEE MICROWAVE and WIRELESS COMPONENTS LETTERS, vol. 17, No. 4, April 2007.

NPL 2—H. Hamada, et al., “300-GHz-band 120 Gb/s Wireless Front-end Based on InP-HEMT PAs and Mixers,” IEEE JOURNAL OF SOLID-STATE CIRCUITS, vol. 55, No. 9, September 2020.

NPL 3—K. Kang, et al., “On-chip vertical tapered solenoid inductor with high self-resonance frequency,” ELECTRONICS LETTERS, vol. 43, No. 16, August 2007.

### SUMMARY

### Technical Problem

Embodiments of the present invention are intended to solve the above problem, and an object is to provide a differential amplifier circuit capable of securing a large CMRR while maintaining low power consumption.

### Solution to Problem

A differential amplifier circuit of embodiments of the present invention includes an amplifier section including a differential pair transistor to which a differential signal is input; and a tail current circuit made up of a short stub provided between a ground terminal of the amplifier section and a ground.

In a configuration example of the differential amplifier circuit of embodiments of the present invention, an electrical length of the short stub is shorter than a quarter wavelength of an operation frequency of the differential amplifier circuit.

A configuration example of the differential amplifier circuit of embodiments of the present invention further includes a capacitance provided in parallel with the short stub between the ground terminal of the amplifier section and the ground.

A configuration example of the differential amplifier circuit of embodiments of the present invention further includes a resistor inserted in series with the capacitance between the ground terminal of the amplifier section and the ground.

A configuration example of the differential amplifier circuit according to embodiments of the present invention further includes an open stub in which one end is connected to the ground terminal of the amplifier section, and the other end is opened, in which an electrical length of the open stub is shorter than a quarter wavelength of an operation frequency of the differential amplifier circuit.

A configuration example of the differential amplifier circuit of embodiments of the present invention further includes a resistor inserted in series between the ground terminal of the amplifier section and the open stub.

In a configuration example of the differential amplifier circuit of embodiments of the present invention, the amplifier section is any one of a source-grounded amplifying circuit including the differential pair transistor, an emitter-grounded amplifying circuit including the differential pair transistor, and a cascode amplifying circuit including the differential pair transistor and a pair of transistors cascode-connected to the differential pair transistor.

### Advantageous Effects of Embodiments of the Invention

According to embodiments of the present invention, by providing the tail current circuit including a short stub between the ground terminal of the amplifier section and the ground, it is possible to ensure a large CMRR while maintaining low power consumption.

### BRIEF DESCRIPTION OF THE DRAWINGS

FIG. 1 is a diagram showing a configuration of a differential amplifier circuit according to embodiments of the present invention.

FIG. 2 is a diagram showing a configuration in which the differential amplifier circuit according to embodiments of the present invention has multiple stages.

FIG. 3 is a diagram showing the gain of the differential amplifier circuit of FIG. 2.

FIG. 4 is a diagram showing the configuration of a differential amplifier circuit that uses a short stub shorter than a quarter wavelength as a tail current circuit.

FIG. 5 is a diagram showing changes in common mode gain when the length of the short stub is changed in the differential amplifier circuit of FIG. 4.

FIG. 6 is a diagram showing a configuration of the differential amplifier circuit according to a first example of embodiments of the present invention.

FIG. 7 is a diagram showing the differential gain and common mode gain of the differential amplifier circuit according to the first example of embodiments of the present invention.

FIG. 8 is a diagram showing a configuration of the differential amplifier circuit according to a second example of embodiments of the present invention.

FIG. 9 is a diagram showing the differential gain and common mode gain of the differential amplifier circuit according to the second example of embodiments of the present invention.

FIG. 10 is a diagram showing a configuration of a differential amplifier circuit according to a third example of embodiments of the present invention.

FIG. 11 is a diagram showing a configuration of a differential amplifier circuit according to a fourth example of embodiments of the present invention.

FIG. 12 is a diagram showing a configuration of a differential amplifier circuit according to the fourth example of embodiments of the present invention.

FIG. 13 is a diagram showing a configuration of the cascode type differential amplifier circuit.

FIG. 14 is a diagram showing a configuration of a conventional differential amplifier circuit.

FIG. 15 is a diagram showing another configuration of the conventional differential amplifier circuit.

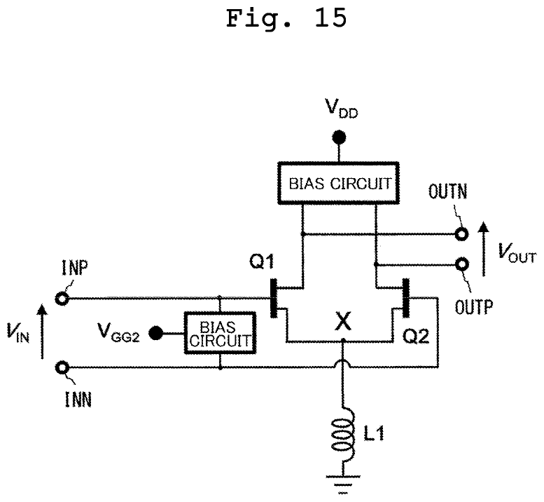

### DETAILED DESCRIPTION OF ILLUSTRATIVE EMBODIMENTS

### Principles of Embodiments of the Invention

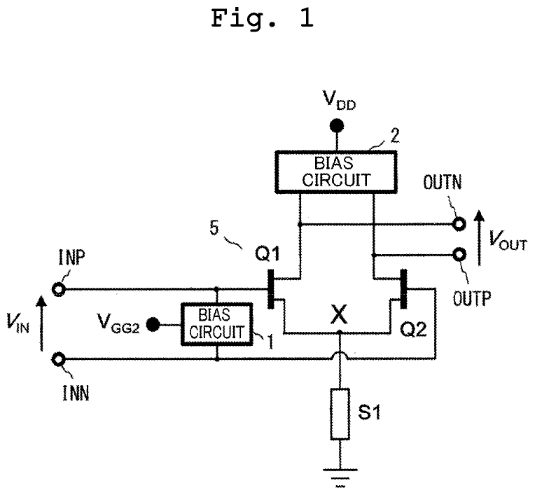

In embodiments of the present invention, the aforementioned problem is solved by applying a circuit based on a transmission line to a tail current source circuit of a differential amplifier circuit. FIG. 1 is a diagram showing a configuration of the differential amplifier circuit according to embodiments of the present invention. The differential amplifier circuit includes a transistor Q1 which has a gate terminal connected to an input port INP and a drain terminal connected to an output port OUTN, a transistor Q2 having a gate terminal connected to the input port INN and a drain terminal connected to an output port OUTP, a bias circuit 1 that supplies a bias voltage V_{GG2} to the gate terminals of the transistors Q1 and Q2, a bias circuit 2 that supplies a power supply voltage V_{DD} to the drain terminals of the transistors Q1 and Q2, and a short stub S1 which has one end connected to the source terminals of the transistors Q1 and Q2 and the other end connected to the ground.

The differential pair transistors Q1 and Q2 constitute an amplifier section 5. The transistors Q1 and Q2 each constitute a source ground amplifier circuit. The gate terminals of the transistors Q1 and Q2 become an input terminal of the amplifier section 5, the drain terminal becomes an output terminal of the amplifier section 5, and the source terminal becomes a ground terminal of the amplifier section 5.

The bias circuit 1 is made up of, for example, a resistor that applies the bias voltage V_{GG2} to the gate terminal of the transistor Q1 and a resistor that applies the bias voltage V_{GG2} to the gate terminal of the transistor Q2. Similarly, the bias circuit 2 is made up of, for example, a resistor that applies a power supply voltage V_{DD} to the drain terminal of the transistor Q1 and a resistor that applies the power supply voltage V_{DD} to the drain terminal of the transistor Q2.

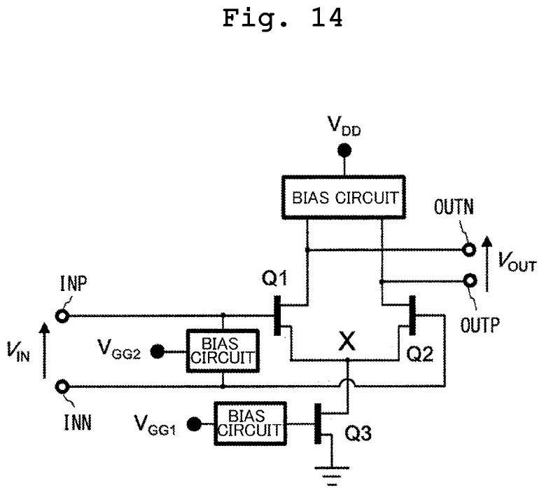

In embodiments of the present invention, a short stub S1 including a transmission line is used as a tail current circuit of the differential amplifier circuit as shown in FIG. 1. By setting the length of the short stub S1 to a quarter wavelength in the operation frequency of the differential amplifier circuit, impedance when the short stub S1 is viewed from the X point reaches a very high value. Thus, it becomes equivalent to the source terminals of the transistors Q1 and Q2 being open, and the differential amplifier circuit of FIG. 1 operates in the same manner as the configuration of FIG. 14.

In embodiments of the present invention, since a current source transistor is not required, the problem of increase in power consumption, which is a problem of a conventional differential amplifier circuit, can be solved. In addition, by using the short stub S1 capable of realizing a symmetrical structure, it is possible to solve a problem in layout due to usage of an asymmetrical inductor.

However, in the configuration shown in FIG. 1, there is a serious problem in the layout of the integrated circuit when applied to a multi-stage amplifier circuit in a frequency band of 300 GHz or more. This problem will be explained below. In the case of an integrated circuit process using an InP substrate or a S1 substrate, the length of a quarter wavelength line in a 300 GHz band takes a value of approximately 100 to 200 μm. This value is an unacceptably large value when considering that the differential amplifier circuit is made into multiple stages.

Normally, in the frequency band of 300 GHz or more, since the gain per transistor is small, it is possible to configure an amplifier circuit having a significant gain first by making the transistors multi-stage as described in NPL 2. In such a multi-stage amplifier circuit, a reduction in loss of an inter-stage matching circuit that connects the amplifier circuits as much as possible is an extremely important design factor for ensuring the gain of the multi-stage amplifier circuit. In order to reduce the loss of the inter-stage matching circuit, it is important to shorten the physical length of the inter-stage matching circuit as much as possible as described in NPL 2.

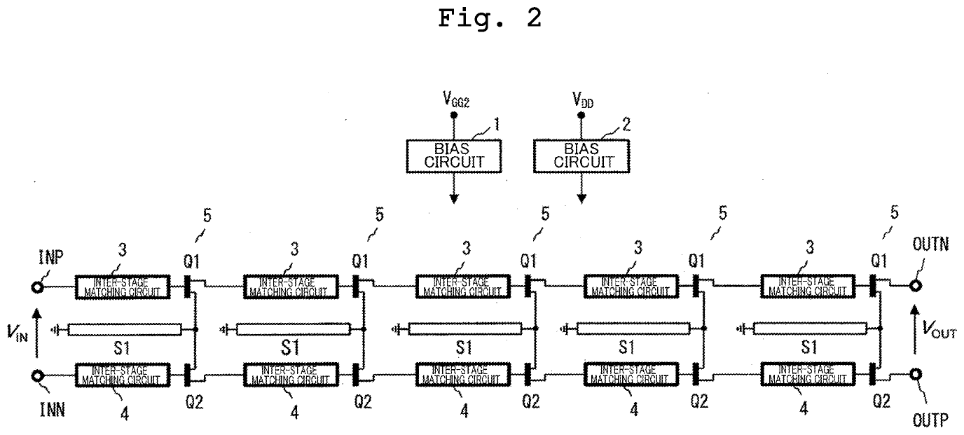

FIG. 2 shows a configuration in which the differential amplifier circuit of FIG. 1 is made in multi-stages. In the example of FIG. 2, five stages of differential amplifier circuits are connected in series. Similarly to FIG. 1, one end of the short stub S1 of each stage is connected to the source terminals of the transistors Q1 and Q2, and the other end thereof is connected to the ground.

The inter-stage matching circuits 3 and 4 of a first stage are inserted between the input ports INP and INN and the gate terminals of the transistors Q1 and Q2 of the first stage. An inter-stage matching circuit 3 of the first stage matches the impedance of the input port INP with the impedance of the gate terminal of the transistor Q1 of the first stage viewed from the input port INP. The inter-stage matching circuit 4 of the first stage matches the impedance of the input port INN with the impedance of the gate terminal of the first stage transistor Q2 viewed from the input port INN.

The input terminal of the inter-stage matching circuit 3 other than the first stage is connected to the drain terminal of the transistor Q1 of the previous stage, and the output terminal is connected to the gate terminal of the transistor Q1 of the subsequent stage. The input terminal of the inter-stage matching circuit 4 other than the first stage is connected to the drain terminal of the transistor Q2 of the previous stage, and the output terminal is connected to the gate terminal of the transistor Q2 of the subsequent stage. The inter-stage matching circuit 3 other than the first stage matches the impedance of the drain terminal of the transistor Q1 of the previous stage with the impedance of the gate terminal of the transistor Q1 of the subsequent stage viewed from the drain terminal. The inter-stage matching circuit 4 other than the first stage matches the impedance of the drain terminal of the transistor Q2 of the previous stage with the impedance of the gate terminal of the transistor Q2 of the subsequent stage viewed from the drain terminal.

The drain terminals of the transistors Q1 and Q2 at the final stage are connected to output ports OUTN and OUTP.

Although the specific connection of the bias circuit is not described in the example shown in FIG. 2, a bias circuit 1 that supplies the bias voltage V_{GG2} to the gate terminals of the transistors Q1 and Q2 of each stage and a bias circuit 2 that supplies the power supply voltage V_{DD} to the drain terminals of the transistors Q1 and Q2 of each stage may be provided.

As is apparent from the layout of FIG. 2, the lengths of the inter-stage matching circuits 3 and 4 cannot be made equal to or less than a quarter wavelength of the operation frequency of the differential amplifier circuit. Therefore, a loss (about 1.5 dB) for a quarter wavelength line is given between stages of the differential amplifier circuit, and it is not possible to constitute a high-gain multi-stage amplifier circuit.

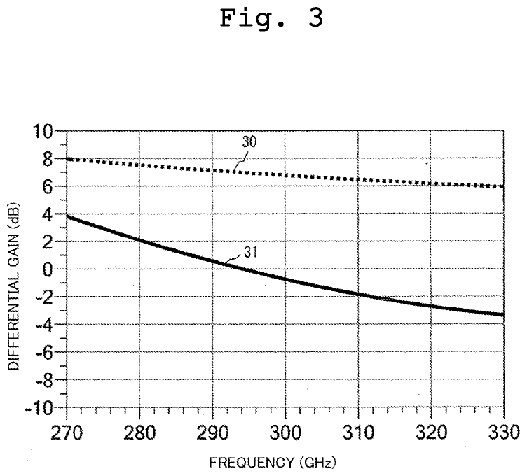

In order to quantitatively explain that the gain of the differential amplifier circuit of FIG. 2 decreases, the gain of the differential amplifier circuit when the short stub S1 having a length of 140 μm corresponding to a quarter wavelength of 300 GHz is used as a tail current circuit is shown in FIG. 3.

Reference numeral 30 of FIG. 3 shows the gain when the inter-stage matching circuits 3 and 4 are matching circuits having an appropriate physical length (approximately 20 to 40 μm) as used in NPL 2. However, it is not practically possible to dispose the inter-stage matching circuits 3 and 4 of this length in the layout shown of FIG. 2.

On the other hand, reference numeral 31 of FIG. 3 shows the gain in the case of a layout which can be actually realized with the length of the inter-stage matching circuits 3 and 4 set to 140 μm.

As is apparent from FIG. 3, when the lengths of the inter-stage matching circuits 3 and 4 are set to 140 μm, it is found that the gain is greatly reduced due to the loss of the quarter wavelength line. For example, at 300 GHz, the gain decreases by 7.5 dB, compared to a case where the lengths of the inter-stage matching circuits 3 and 4 are set to appropriate physical lengths. That is, it is found that the loss increase of 1.5 dB, which is the loss of the quarter wavelength line, occurs per stage. Further, since the loss of the transmission line increases as the frequency increases, it is found that a difference in gain between the case 30 and the case 31 of FIG. 3 increases with the increase in the frequency.

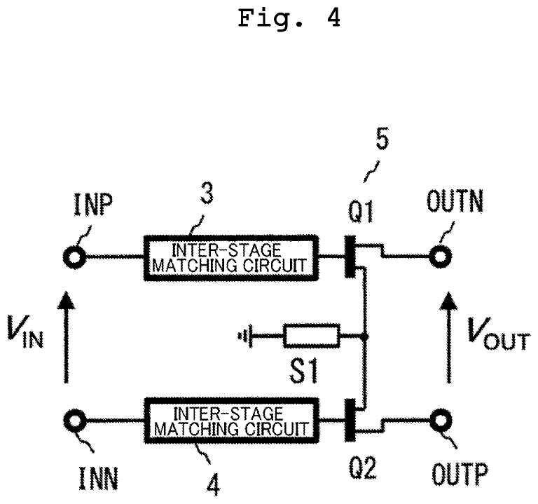

Therefore, it is desirable that the length of the short stub S1 is made shorter than a quarter wavelength of the operation frequency of the differential amplifier circuit. Therefore, the configuration shown in FIG. 4 is considered. In the configuration shown in FIG. 4, the source terminals of the transistors Q1 and Q2 are not completely opened, and the configuration is equivalent to a configuration in which an inductance is inserted between the source terminals of the transistors Q1 and Q2 and the ground. The inductance has the effect of degeneration of the gain of the source ground amplifier circuit.

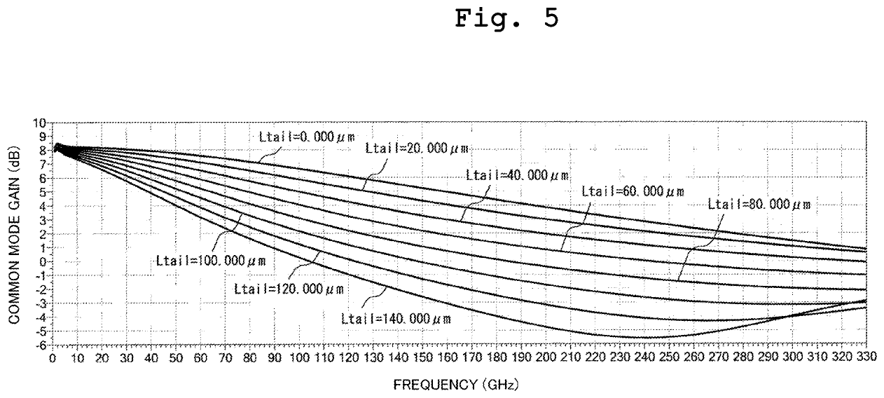

FIG. 5 shows a change in the common mode gain of the differential amplifier circuit when a length Ltail of the short stub S1 shown in FIG. 4 is changed to 0 to 140 μm. In the example shown in FIG. 5, the lengths of the inter-stage matching circuits 3 and 4 are set to 140 μm. According to FIG. 5, by setting the Ltail to 140 μm corresponding to the quarter wavelength of the 300 GHz band, it is found that the gain is greatly reduced in 200 to 300 GHz.

Also, it is found that even when the short stub S1 shorter than the quarter wavelength is used, the gain is reduced by the gain degeneration effect. The gain degeneration effect obtained by making the short stub S1 shorter than a quarter wavelength is very small at a low frequency. However, since the gain of the transistor is small in the vicinity of 300 GHz, it is found that even when a short stub S1 having a length of 80 μm is used, the common mode gain can be set to 0 dB or less. Therefore, if the circuit shown in FIG. 4 is made in multi-stages, a differential amplifier circuit having a large CMRR can be realized even with a stub length of 80 μm.

As described above, in embodiments of the present invention, a short stub made up of a transmission line is used as the tail current circuit of the differential amplifier circuit. In particular, in order to reduce the matching loss of the inter-stage matching circuit which is important when designing the multi-stage amplifier circuit, a stub length shorter than a quarter wavelength is used, and common mode gain is reduced by taking advantage of the fact that the short stub acts as an inductor with an equivalent gain degeneration effect.

### EXAMPLE 1

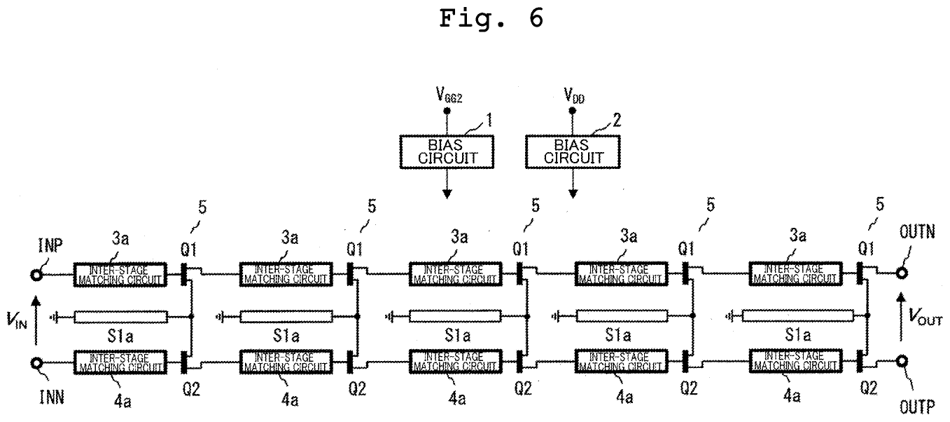

Referring to the drawings, a description will be given of examples of embodiments of the present invention. FIG. 6 is a diagram showing a configuration of a differential amplifier circuit according to a first example of embodiments of the present invention. This example is a specific example of the configuration described in the principle of embodiments of the present invention. In this example, the short stub Sia and the inter-stage matching circuits 3a and 4a are made to have the same length that is shorter than a quarter wavelength of the operation frequency of the differential amplifier circuit. In the example shown in FIG. 6, five stages of differential amplifier circuits are connected in series as in FIG. 2.

Similarly to FIG. 2, in the example shown in FIG. 6, a bias circuit 1 which supplies a bias voltage V_{GG2} to the gate terminals of the transistors Q1 and Q2 of each stage and a bias circuit 2 which supplies the power supply voltage V_{DD} to the drain terminals of the transistors Q1 and Q2 of each stage are provided.

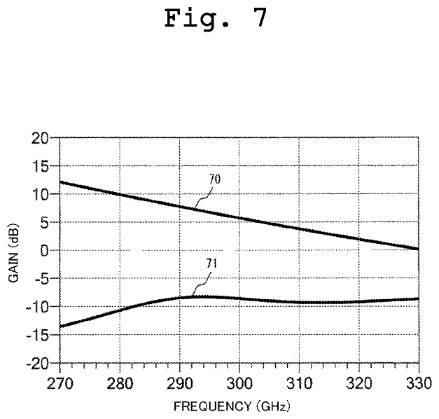

In this example, the calculation results of the differential gain and the common mode gain of the differential amplifier circuit when the lengths of the short stub S1a and the inter-stage matching circuits 3a and 4a are set to 80 μm are shown in FIG. 7. In FIG. 7, reference numeral 70 denotes a differential gain, and reference numeral 71 denotes a common mode gain.

It is understood from FIG. 7 that the differential gain is larger than that in the case 31 of FIG. 3 by shortening the inter-stage matching circuits 3a and 4a. In addition, the common mode gain is suppressed to 0 dB or less. As a result, the CMRR defined by the ratio of the differential gain to the common mode gain can be secured by 15 dB at 300 GHz.

### EXAMPLE 2

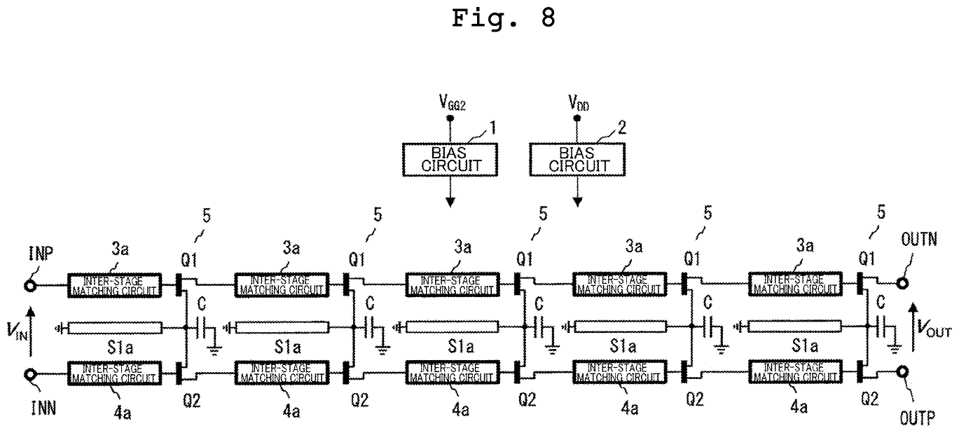

Next, a description will be given of a second example of embodiments of the present invention. FIG. 8 is a diagram showing a configuration of a differential amplifier circuit according to the second example of embodiments of the present invention. In this example, in order to obtain a larger common mode rejection ratio than in the first example, a capacitance C is added between the source terminals of the transistors Q1 and Q2 and the ground in parallel with the short stub S1a.

The capacitance C constitutes an LC resonance circuit at the inductance L of the short stub S1a and the following frequency F. Since the LC resonance circuit is a parallel resonance circuit, it becomes equivalent to open at a resonance frequency F when viewed from transistors Q1 and Q2. Therefore, in this example, a very large CMRR can be obtained.

Equation(1): F=1/(2π√LC) (1)

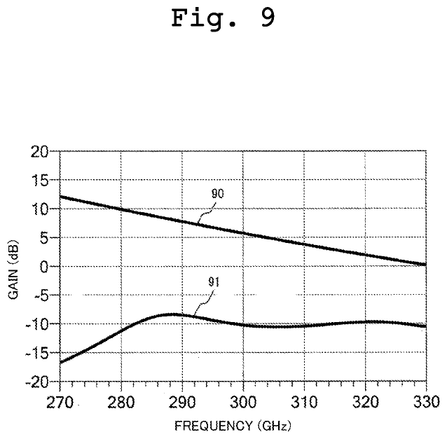

This resonance frequency F may be set to the operation frequency of the differential amplifier circuit. FIG. 9 shows the calculation results of the differential gain and the common mode gain of the differential amplifier circuit of this example. Similarly to FIG. 7, in the example of FIG. 9, the lengths of the short stub S1a and the inter-stage matching circuits 3a and 4a are set to 80 μm. The value of the capacitance C is 4fF. Reference numeral 9o of FIG. 9 denotes a differential gain, and reference numeral 91 denotes a common mode gain.

As can be seen from the comparison between FIG. 9 and FIG. 7, by this example, it is possible to reduce the common mode gain by 2 dB or more at 300 GHz. Thus, the CMRR of the differential amplifier circuit is improved by 2 dB or more.

As a further effect of this example, the short stub S1a can be shortened. That is, if the short stub S1a is shortened within a range in which the value of the equation (1) becomes the same resonance frequency F and the capacitance C is increased instead, it is possible to obtain the same CMRR improvement effect as a case where the short stub S1a is long.

For example, when the inter-stage matching circuits 3a and 4a are made shorter, the short stub S1a disposed between the inter-stage matching circuits 3a and 4a may be made shorter. In other words, it is possible to cope with the above problem, by reducing the inductance L of the equation (1) and increasing the capacitance C. In general, in a frequency band exceeding 300 GHz, the width of the inductance L (length of the short stub S1a) and the capacitance C, which can be realized by the layout, is determined. Therefore, the length of the short stub S1a which can be laid out and the value of the capacitance C can be found within the range that satisfies the equation (1). Thus, in this example, by appropriately selecting the length of the short stub S1a and the value of the capacitance C, it is possible to improve the degree of freedom in layout of the differential amplifier circuit.

### EXAMPLE 3

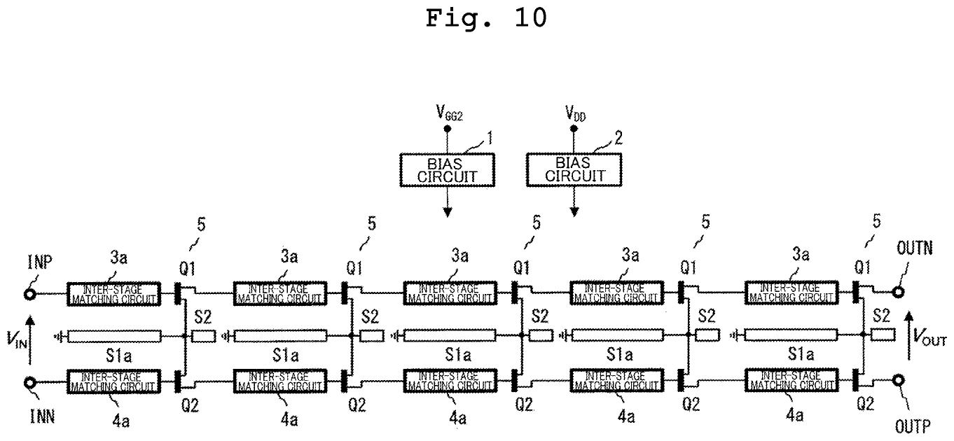

Next, a description will be given of a third example of embodiments of the present invention. FIG. 10 is a diagram showing a configuration of a differential amplifier circuit according to a third example of embodiments of the present invention. In this example, an open stub S2 which is a transmission line having one end connected to the source terminals of the transistors Q1 and Q2 and the other end opened is provided instead of the capacitance C in the second example. This example provides a configuration which can be realized when a small capacitance is required to be used in the second example.

In general, a small capacitance of about several fF has a large fringe effect, and it is difficult to estimate an accurate value at the time of layout. Therefore, as shown in FIG. 10, it is considered that the capacitance C is replaced with an open stub S2. The open stub S2 sufficiently shorter than a quarter wavelength of an operation frequency of the differential amplifier circuit equivalently functions as a parallel capacitance of the short stub Sia as in the configuration of FIG. 8. Therefore, this example has the same common mode rejection effect as that of the second example.

By determining the length of the open stub S2 so that the equivalent capacity satisfies the equation (1), the capacity of several fF which is generally difficult to be realized can be realized with high accuracy.

### EXAMPLE 4

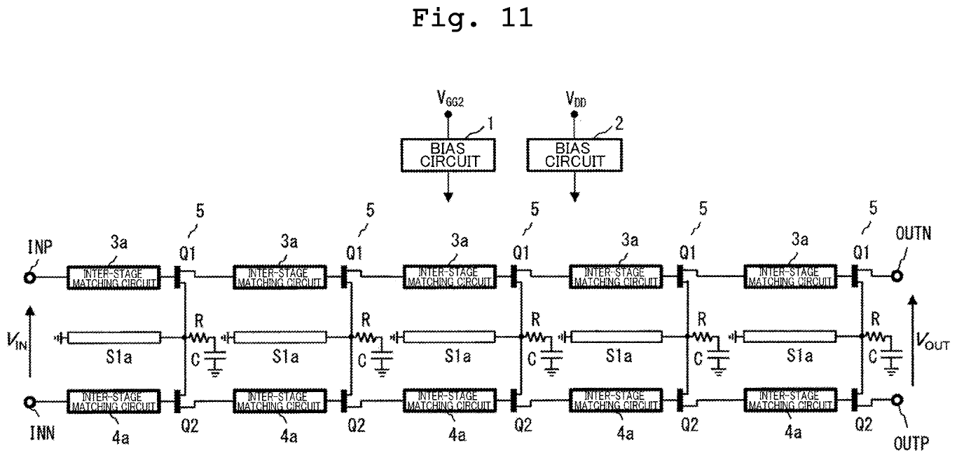

Next, a fourth example of embodiments of the present invention will be described. FIG. 11 is a diagram showing a configuration of a differential amplifier circuit according to the fourth example of embodiments of the present invention. In this example, a resistor R is inserted in series with the capacitance C between the source terminals of the transistors Q1 and Q2 and the ground in the second example.

According to this example, the Q value of resonance determined by the equation (1) can be reduced, and the common mode rejection effect can be exhibited over a wider band.

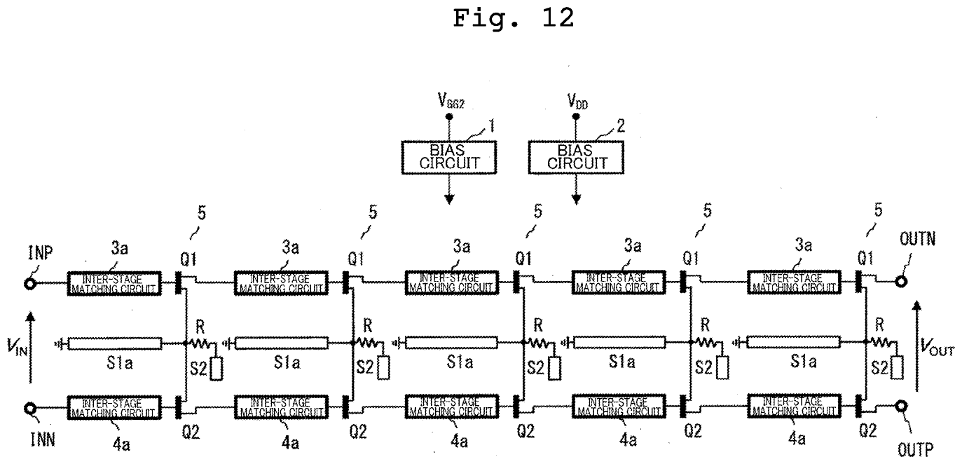

As shown in FIG. 12, the resistor R can also be applied to the third example. In the example shown in FIG. 12, a resistor R is inserted between the source terminals of the transistors Q1 and Q2 and the open stub S2.

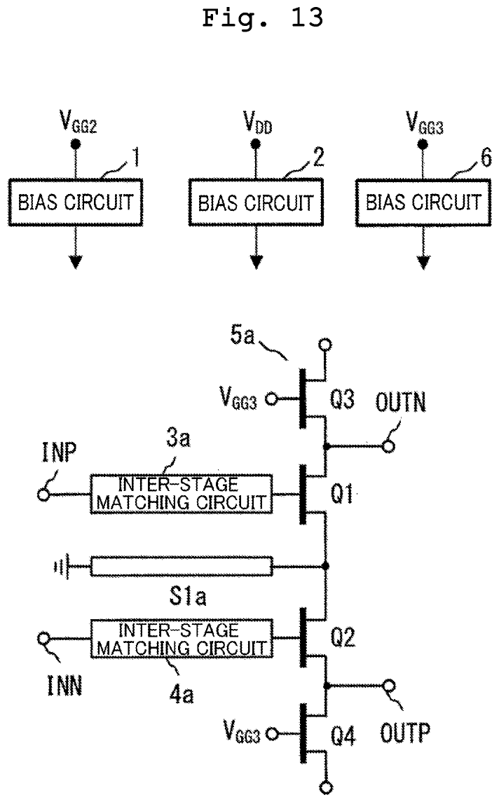

In the first to fourth examples, an example of a differential amplifier circuit using two transistors Q1 and Q2 constituting a source ground amplifier circuit has been each described, but embodiments of the present invention may be applied to a cascode type differential amplifier circuit. FIG. 13 is a diagram showing a configuration of the cascode type differential amplifier circuit. The cascode type differential amplifier circuit includes a transistor Q1 whose gate terminal is connected to the output terminal of the inter-stage matching circuit 3a and whose drain terminal is connected to the output port OUTN, a transistor Q2 whose gate terminal is connected to the output terminal of the inter-stage matching circuit 4a and whose drain terminal is connected to the output port OUTP, a transistor Q3 in which a bias voltage V_{GG3} is applied to a gate terminal and a source terminal is connected to a drain terminal of the transistor Q1, a transistor Q4 in which the bias voltage V_{GG3} is applied to a gate terminal and a source terminal is connected to a drain terminal of the transistor Q2, and a short stub S1a which has one end connected to the source terminals of the first and second connection terminals Q1 and Q2 and the other end connected to the ground. The transistors Q1 and Q2 and the transistors Q3 and Q4 cascode-connected to the transistors Q1 and Q2 form an amplifier section 5a (a cascode amplifier circuit).

As described in the first to fourth examples, the bias voltage V_{GG2} is supplied to the gate terminals of the transistors Q1 and Q2 of each stage from the bias circuit 1. Further, the bias voltage V_{GG3} may be supplied from the bias circuit 6 to the gate terminals of the transistors Q3 and Q4 of each stage, and the power supply voltage V_{DD} may be supplied from the bias circuit 2 to the drain terminals of the transistors Q3 and Q4 of each stage.

When the differential amplifier circuit shown of FIG. 13 is made a multi-stage, the input terminal of the inter-stage matching circuit 3a other than the first stage may be connected to the drain terminal of the transistor Q1 of the previous stage and the source terminal of the transistor Q3, and the output terminal of the inter-stage matching circuit 3a may be connected to the gate terminal of the transistor Q1 of the subsequent stage. The input terminal of the inter-stage matching circuit 4a other than the first stage may be connected to the drain terminal of the transistor Q2 of the previous stage and the source terminal of the transistor Q4, and the output terminal of the inter-stage matching circuit 4a may be connected to the gate terminal of the transistor Q2 of the subsequent stage. The drain terminal of the transistor Q1 at the final stage and the source terminal of the transistor Q3 are connected to an output port OUTN. The drain terminal of the transistor Q2 and the source terminal of the transistor Q4 at the final stage are connected to the output port OUTP.

FIGS. 1, 2, 4, 6, 8, and 10 to 13 show examples in which field effect transistors are used as the transistors Q1 to Q4, but bipolar transistors may be used. When the bipolar transistor is used, in the above description, the gate terminal may be replaced by the base terminal, the drain terminal may be replaced by the collector terminal, and the source terminal may be replaced by the emitter terminal (ground terminal). In FIGS. 1, 2, 4, 6, 8, and 10 to 12, when a bipolar transistor is used, it goes without saying that the transistors Q1 and Q2 each constitute an emitter ground amplifier circuit.

### INDUSTRIAL APPLICABILITY

Embodiments of the present invention can be applied to a differential amplifier circuit.

### REFERENCE SIGNS LIST

1, 2, 6 Bias circuit
3a, 4, 4a Inter-stage matching circuits
5, 5a Amplifier section
Q1 to Q4 Transistor
C Capacitance
R Resistance
S1, S1a Short stub
S2 Open stub

1.-7. (canceled)

8. A differential amplifier circuit comprising:
an amplifier section comprising a differential pair transistor to which a differential signal is input; and
a tail current circuit made up of a short stub provided between a ground terminal of the amplifier section and a ground.

9. The differential amplifier circuit according to claim 8, wherein an electrical length of the short stub is shorter than a quarter wavelength of an operation frequency of the differential amplifier circuit.

10. The differential amplifier circuit according to claim 9, further comprising a capacitance provided in parallel with the short stub between the ground terminal of the amplifier section and the ground.

11. The differential amplifier circuit according to claim 10, further comprising a resistor inserted in series with the capacitance between the ground terminal of the amplifier section and the ground.

12. The differential amplifier circuit according to claim 9, further comprising an open stub having a first end connected to the ground terminal of the amplifier section and a second end that is opened, wherein an electrical length of the open stub is shorter than a quarter wavelength of the operation frequency of the differential amplifier circuit.

13. The differential amplifier circuit according to claim 8, further comprising a capacitance provided in parallel with the short stub between the ground terminal of the amplifier section and the ground.

14. The differential amplifier circuit according to claim 8, further comprising an open stub having a first end connected to the ground terminal of the amplifier section and a second end that is opened, wherein an electrical length of the open stub is shorter than a quarter wavelength of an operation frequency of the differential amplifier circuit.

15. The differential amplifier circuit according to claim 14, further comprising a resistor inserted in series between the ground terminal of the amplifier section and the open stub.

16. The differential amplifier circuit according to claim 15, wherein the amplifier section comprises:
a source-grounded amplifying circuit comprising the differential pair transistor;
an emitter-grounded amplifying circuit comprising the differential pair transistor; or
a cascode amplifying circuit comprising the differential pair transistor and a pair of transistors cascode-connected to the differential pair transistor.

17. The differential amplifier circuit according to claim 8, wherein the amplifier section comprises:
a source-grounded amplifying circuit comprising the differential pair transistor;
an emitter-grounded amplifying circuit comprising the differential pair transistor; or
a cascode amplifying circuit comprising the differential pair transistor and a pair of transistors cascode-connected to the differential pair transistor.

18. A method of providing a differential amplifier circuit, the method comprising:
providing an amplifier section comprising a differential pair transistor to which a differential signal is input; and
providing a tail current circuit made up of a short stub provided between a ground terminal of the amplifier section and a ground.

19. The method according to claim 18, wherein an electrical length of the short stub is shorter than a quarter wavelength of an operation frequency of the differential amplifier circuit.

20. The method according to claim 19, further comprising providing a capacitance in parallel with the short stub between the ground terminal of the amplifier section and the ground.

21. The method according to claim 20, further comprising inserting a resistor in series with the capacitance between the ground terminal of the amplifier section and the ground.

22. The method according to claim 19, further comprising providing an open stub having a first end connected to the ground terminal of the amplifier section and a second end that is opened, wherein an electrical length of the open stub is shorter than a quarter wavelength of the operation frequency of the differential amplifier circuit.

23. The method according to claim 18, further comprising providing a capacitance in parallel with the short stub between the ground terminal of the amplifier section and the ground.

24. The method according to claim 18, further comprising providing an open stub having a first end connected to the ground terminal of the amplifier section and a second end that is opened, wherein an electrical length of the open stub is shorter than a quarter wavelength of an operation frequency of the differential amplifier circuit.

25. The method according to claim 24, further comprising inserting a resistor in series between the ground terminal of the amplifier section and the open stub.

26. The method according to claim 25, wherein the amplifier section comprises:
a source-grounded amplifying circuit comprising the differential pair transistor;
an emitter-grounded amplifying circuit comprising the differential pair transistor; or
a cascode amplifying circuit comprising the differential pair transistor and a pair of transistors cascode-connected to the differential pair transistor.

27. The method according to claim 18, wherein the amplifier section comprises:
a source-grounded amplifying circuit comprising the differential pair transistor;
an emitter-grounded amplifying circuit comprising the differential pair transistor; or
a cascode amplifying circuit comprising the differential pair transistor and a pair of transistors cascode-connected to the differential pair transistor.
